(19) United States
(12) Patent Application Publication
(10) Pub. No.: US 2007/0160760 A1
(43) Pub. Date: Jul. 12, 2007

(54) Methods of forming phase change material thin films and methods of manufacturing phase change memory devices using the same

(75) Inventors: Woong-chul Shin, Suwon-si (KR); Yoon-ho Khang, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/509,728

(22) Filed: Aug. 25, 2006

(30) Foreign Application Priority Data
Jan. 10, 2006 (KR) 10-2006-0002692

(51) Int. Cl. C23C 16/00

(52) U.S. Cl. 427/255.35

(57) ABSTRACT

A method of forming a phase change material thin film comprises supplying a first precursor including Ge and a second precursor including Te into a reaction chamber concurrently to form a GeTe thin film on a substrate. A second precursor including Te and a third precursor including Sb are concurrently supplied into the reaction chamber and onto the GeTe thin film to form a SbTe thin film. The supplying of the first and second precursors and the supplying of the second and third precursors to form a GeSbTe thin film.

### PRIORITY STATEMENT

This non-provisional U.S. patent application claims priority under 35 U.S.C. § 119 to Korean Patent Application No. 10-2006-0002692, filed on Jan. 10, 2006, in the Korean Intellectual Property Office (KIPO) the entire contents of which is incorporated herein by reference.

### BACKGROUND

### Description of the Related Art

Related art memory devices suitable for electronic instruments, such as, computers, hand-held electronic devices, etc. require non-volatile characteristics. Non-volatile memory devices retain stored data even when the power supply is shut down. In addition, non-volatile memory devices may require, for example, lower price, higher integration density, lower power consumption, higher speed to be competitive in different markets.

An example related art non-volatile memory device is a flash memory. However, flash memory may not operate at a sufficient speed. Another related art non-volatile memory device is a magneto-resistance random access memory (MRAM), which uses different directions of magnetic spins, a ferroelectric random access memory (FRAM), which uses a polarization phenomenon of ferroelectrics, a phase-change random access memory (PRAM), which uses a phase change material in which a phase of a thin film is changed by an external energy, etc.

Related art PRAMs store data using the resistance difference between an amorphous state and a crystal state of a chalcogenide material whose phase is changeable by an externally applied energy. For example, a related art PRAM stores data in the state of ‘0’ or ‘1’ using the resistance difference caused by a reversible phase transition of a phase change material layer composed of, for example, germanium (Ge) antimony (Sb) and tellurium (Te) (GST) as chalcogenide compound in accordance with an amplitude and a length of applied pulse.

In one example, one of a reset current and a set current may be transferred from a transistor through a lower electrode to a phase change material layer to cause the phase transition. The reset current transitions the related art phase change material layer to an amorphous state of a higher resistance, while the set current transitions the phase change material layer to a crystalline state of lower resistance. An upper portion of the lower electrode may be connected to the phase change material layer, and a lower portion of the lower electrode may contact a drain of the transistor.

In related art methods of fabricating PRAM devices, controlling a growth rate of the phase change material layer during fabrication may be difficult when a GST phase change material layer is formed using a physical vapor deposition (PVD) process (e.g., sputtering) or an evaporation deposition process. As a result, the structure of the phase change material layer may not be sufficiently dense, and/or the phase change material layer may not have a face centered cubic (FCC) crystal structure.

In the related art, when the phase change material layer is formed using a PVD method, characteristics of the phase change material layer may deteriorate because controlling a composition ratio of germanium (Ge), antimony (Sb) and/or tellurium (Te) inside the phase change material layer may be difficult. Further, because a deposition speed of the phase change material layer deposited by the PVD process is relatively slower, related art fabrication methods may require an increased amount of time and/or cost to form phase change material layers. In addition, related art PVD methods may be more difficult to employ in related art methods of fabricating more highly-integrated devices with a three-dimensional (3D) structure because related art PVD methods may have relatively poor step coverage characteristics. This may result in deterioration of electrical characteristics of related art memory devices using phase change material layers formed by related art PVD methods.

### SUMMARY

Example embodiments of the present invention relate to methods of forming phase change material thin films and methods of manufacturing phase change memory devices using the same. At least one example embodiment provides a method of forming a phase change material thin film having improved thin film characteristics using an organic metal chemical vapor deposition method, and at least one example embodiment provides a method of manufacturing a phase change memory device using the same.

At least one example embodiment provides a method of forming a phase change material layer having improved thin film characteristics.

At least one other example embodiment provides a method of manufacturing a phase change memory device using the method of forming a phase change material thin film.

In at least one example embodiment, a first precursor including Ge and a second precursor including Te may be supplied into a reaction chamber concurrently to form a GeTe thin film on a substrate. A second precursor including Te and a third precursor including Sb may be supplied onto the GeTe layer concurrently to form a SbTe thin film. The first and second precursors and the second and third precursors may be repeatedly supplied to form a GeSbTe thin film.

In at least some example embodiments, an inert gas and a reaction gas may be supplied into the reaction chamber while supplying the first and second precursors, and supplying the second and third precursors.

In at least some example embodiments, a purge process may be performed after the precursors have been supplied. The purge process may include stopping supplying the precursors into the reaction chamber, and supplying an inert gas and a reaction gas to remove the first, second and third precursors physically attached, but not reacted.

In at least some example embodiments, a flow rate of a carrier gas of each of the first precursor (e.g., Ge) and the second precursor (e.g., Te) may be about 10 to about 400 sccm, inclusive, and a component ratio of the supplied first and second precursors may be about 1:1. A total flow rate of the supplied carrier gases may be about 200 sccm. A flow rate of a carrier gas of each of the second precursor (e.g., Te and the third precursor (e.g., Sb) may be about 10 to about 400 sccm, inclusive, and a component ratio of the supplied second and third precursors may be about 3:2. A total flow rate of the supplied carrier gases may be about 200 sccm.

Each precursor may be supplied at a temperature of about 300 to about 500° C., inclusive for about 0.1 to about 3.0 seconds, inclusive under a pressure of about 0.5 to about 10 Torr, inclusive.

In at least some example embodiments, the inert gas may be argon (Ar) gas, nitrogen (N₂) gas or the like, and the reaction gas may use hydrogen (H₂) gas, ammonia (NH₃) gas or the like.

In at least some example embodiments, a phase change material thin film may be formed by repeatedly supplying the first and second precursors concurrently, the second and third precursors concurrently, and performing the purging process as one cycle.

According to at least one other example embodiment, in a method of manufacturing a phase change memory device, a lower electrode may be formed on a substrate having lower component elements of a memory device formed thereon. A phase change material thin film may be formed on the lower electrode, and an upper electrode may be formed on the phase change material thin film. In at least this example embodiment, the phase change material thin film may be formed by supplying a first precursor including Ge and a second precursor including Te into a reaction chamber concurrently to form a GeTe thin film on the substrate, supplying a second precursor including Te and a third precursor including Sb onto the GeTe thin film concurrently to form a SbTe thin film, and repeatedly supplying the first and second precursors concurrently and the second and third precursors concurrently to form a GeSbTe layer.

### BRIEF DESCRIPTION OF THE DRAWINGS

Example embodiments will be described with regard to the attached drawings in which:

FIG. 1 is a flow diagram illustrating a method of forming a phase change material thin film, according to an example embodiment;

FIG. 2 is a processing timing sheet illustrating a method of forming a phase change material thin film, according to an example embodiment;

FIG. 3 is a graph illustrating component ratios of Ge, Sb, and Te in a phase change material thin film, according to an example embodiment;

FIG. 4 is a graph illustrating X-ray diffraction analysis of the crystal structure of a phase change material thin film, according to an example embodiment;

FIG. 5 is an electron microscope photograph illustrating a surface of a phase change material thin film, according to an example embodiment;

FIGS. 6A through 6K are sectional views illustrating a method of manufacturing a phase change semiconductor memory device, according to an example embodiment; and

FIGS. 7A through 7E are sectional views illustrating a method of manufacturing a phase change semiconductor memory device, according to another example embodiment.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions are exaggerated for clarity.

Detailed illustrative example embodiments are disclosed herein. However, specific structural and functional details disclosed herein are merely representative for purposes of describing example embodiments. However, the present invention may be embodied in many alternate forms and should not be construed as limited to only the example embodiments set forth herein.

Accordingly, while example embodiments are capable of various modifications and alternative forms, example embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the present invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

In the drawings, like numbers refer to like elements throughout the specification. The thicknesses of layers and regions are exaggerated for clarity.

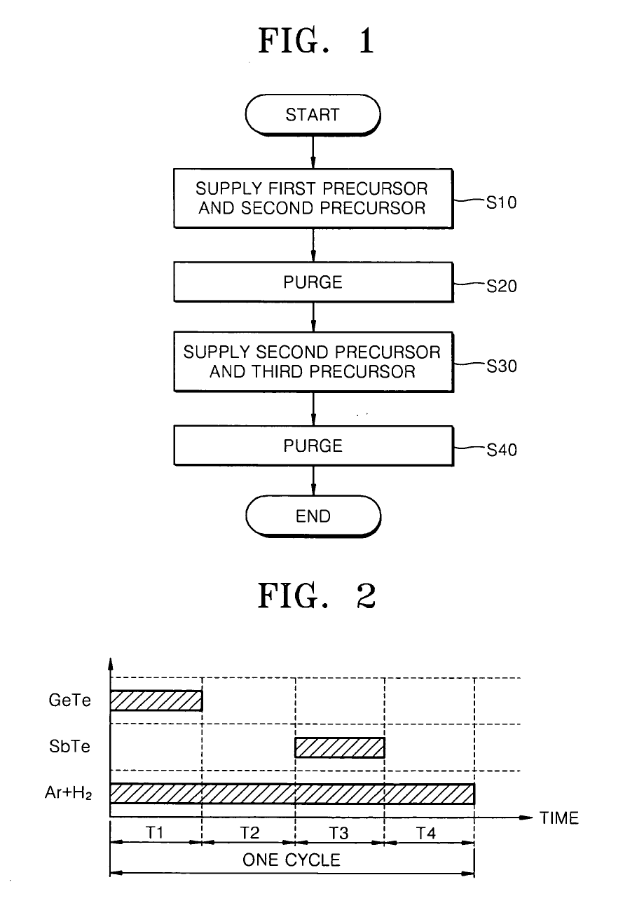

FIG. 1 is a flow diagram illustrating a method of forming a phase change material thin film, according to an example embodiment. FIG. 2 is a processing timing sheet illustrating a method of forming a phase change material thin film, according to an example embodiment.

Referring to FIGS. 1 and 2, a first precursor including germanium (Ge), a second precursor including tellurium (Te) and a third precursor including antimony (Sb) may be prepared. The first, second, and third precursors may be, for example, (CH₂CH═CH₂)₄Ge, Te(i-C₃H₇)₂, and Sb(i-C₃H₇)₃, respectively.

Alternatively, the first precursor may be at least one selected from (CH₃)₄Ge, (C₂H₅)₄Ge, (n-C₄H₉)₄Ge, (i-C₄H₉)₄Ge, (C₆H₅)₄Ge, (CH₂═CH)₄Ge, (CH₂CH═CH₂)₄Ge, (CF₂═CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH═CH₂)Ge, (CH₃)₃(CH₂CH═CH₂)Ge, (C₂H₅)₃(CH₂CH═CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄, and Ge[N(Si(CH₃)₃)₂]₄.

The second precursor may be at least one selected from Te(CH₃)₂, Te(C₂H₅)2, Te(n-C₃H₇)₂, Te(i-C₃H₇)₂, Te(t-C₄H₉)₂, Te(i-C₄H₉)₂, Te(Ch₂=CH)₂, Te(CH₂CH═CH₂)₂, and Te[N(Si(CH₃)₃)₂]₂.

The third precursor may be at least one selected from Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃, and Sb[N(Si(CH₃)₃)₂]₃.

The precursor may be used singly, or two or more precursors may be mixed and used.

An object on or in which the phase change material thin film will be formed may be loaded into a reaction chamber. An inert gas and a reaction gas may be supplied to maintain a desired process pressure and process temperature within the reaction chamber.

Referring to FIG. 1, at S10, a first precursor and a second precursor may be concurrently or simultaneously supplied into the reaction chamber for a time T1 to form a GeTe layer. Each of the first precursor and second precursor may be supplied along with a respective carrier gas. The carrier gases may include an inert gas such as argon gas, nitrogen gas or the like. In at least one example embodiment, a supply ratio of the first and second precursors (e.g., Ge and Te), may be about 1:1, and a flow rate of the supplied carrier gas for each of the first and second precursor may be about 10 to about 400 sccm, inclusive. A flow rate of the carrier gas of each of the first and second precursor (e.g., Ge and Te) may be about 100 sccm. A total flow rate of the carrier gases and the first and second precursors may be about 200 sccm.

A mixture gas including argon (Ar) as an inert gas and hydrogen (H₂) as a reaction gas may be supplied to the reaction chamber as a process gas. The mixture gas may be supplied at a flow rate of about 10 to about 1000 sccm, inclusive. In at least one example, the flow rate of the mixture gas may be about 400 sccm. The mixture ratio of the mixture gas may be about 1:1. In at least this example embodiment, the process gas may be supplied (e.g., continuously) until the processing operation(s) are complete, and may be used to maintain an ambient temperature inside the reaction chamber during the formation of a thin film.

The thin film may be formed on a semiconductor substrate such as a silicon wafer, an SOI substrate, a metal oxide single crystal substrate (e.g., an aluminum oxide (Al₂O₃) a single crystal substrate, a strontium titanium oxide (SrTiO₃) single crystal substrate, or the like), or any other suitable substrate. In at least this example embodiment, an electrode, a conductive layer, a conductive layer pattern, an insulating layer and/or an insulating layer pattern may be formed on the substrate. The phase change thin film may be formed, for example, directly on the object or may be formed on the electrode, the conductive layer, the conductive layer pattern, the insulating layer or the insulating layer pattern.

The supplying of the first and second precursor at S10 may be performed at a temperature of about 300 to about 500° C., inclusive, for about 0.1 to about 3.0 seconds (s), inclusive, under a pressure of about 0.5 to about 10 Torr, inclusive. In at least one example, the first and second precursors may be supplied at a temperature of about 400° C. for about 0.9 s at a pressure of about 2 Torr.

Still referring to FIGS. 1 and 2, a purge process may be performed at S20. The purge process may include stopping the supply of the first and second precursor in the reaction chamber for a time T2, and removing portions of the first and second precursors, which are not chemically deposited on the substrate, from the reaction chamber. The portions of the first and second precursors may be removed using the inert gas and the reaction gas as a process gas. In at least this example embodiment, the inert gas and the reaction gas may remove the portions of the first and second precursors, which are physically attached to the chemically-deposited portions thereof on the substrate and the non-reacted portions of precursors remaining inside the reaction chamber.

Referring still to FIGS. 1 and 2, at S30 a second precursor and a third precursor may be supplied (e.g., concurrently) into the reaction chamber for a time T3 to form a SbTe layer. Each of the second and third precursor may be supplied along with a carrier gas. The carrier gas may include an inert gas such as argon gas, nitrogen gas or the like.

At S30, a supply ratio of the second and third precursors (e.g., Te and Sb, respectively) may be about 3:2. A flow rate of the carrier gas for each of the second and third precursor may be about 10 to about 400 sccm, inclusive. In at least this example embodiment, a flow rate of the carrier gas for the second and third precursor may be about 100 sccm, and a total flow rate of the carrier gas and the second and third precursors may be about 200 sccm.

The second and third precursors may be supplied at a temperature of about 300 to about 500° C., inclusive, for about 0.1 to about 3.0 s, inclusive at a pressure of about 0.5 to about 10 Torr, inclusive. In at least one example, the second and third precursors may be supplied at a temperature of about 400° C. for about 0.5 s under a pressure of about 2 Torr.

Continuing to refer to FIGS. 1 and 2, the supply of the second precursor and the third precursor may be stopped and portions of the second and third precursors not chemically deposited, but remaining in the reaction chamber, may be purged from the reaction chamber for a time T4 at S40. In at least one example, the inert gas and the reaction gas may be used to remove portions of the second and third precursors physically attached to other portions of the second and third precursors chemically-deposited on the substrate. The inert gas and the reaction gas may also be used to remove non-reacted portions of the precursors remaining in the reaction chamber.

As a result, a GeSbTe phase change material thin film having a GeTe/SbTe structure with denser layer properties and/or lower resistance properties may be formed on a substrate without using a plasma process.

According to at least one example embodiment, the supply time and the flow rate of the precursors may be controlled, which may enable easier controlling of component ratios of precursors, such as, Ge, Sb and Te. The Ge, Sb and Te may be component elements of the resultant GeSbTe layer.

S10 through S40 of FIG. 1 may be repeated until the GeSbTe thin film is formed to a desired thickness.

In at least one example embodiment, when the process shown in FIG. 1 is repeated between about 40 and about 60 times (e.g., about 50 times), the phase change material thin film formed on the substrate may have a thickness of about 1000 Å.

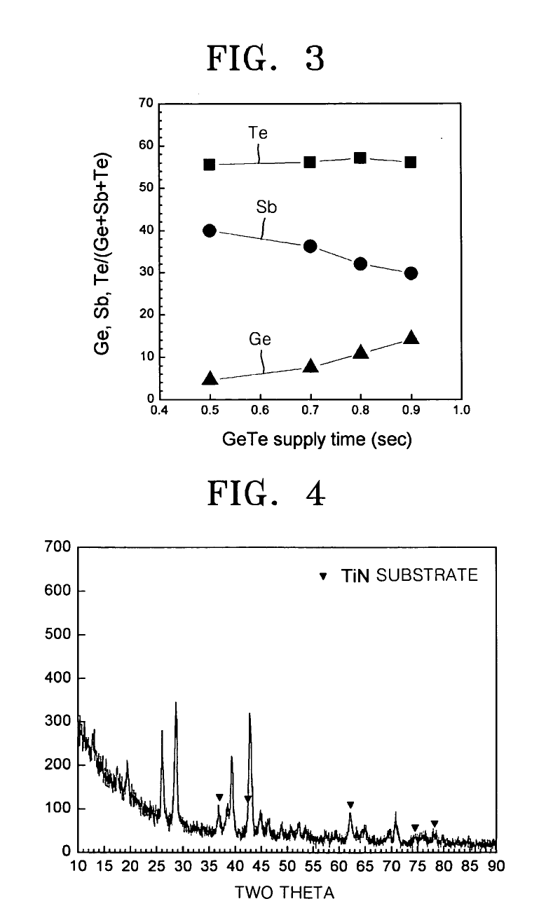

FIG. 3 is a graph illustrating component ratios of Ge, Sb and Te of the phase change material thin film formed using a method of forming the phase change material thin film, according to at least one example embodiment. The graph illustrates the result of the component ratios when the supply time of the second precursor (Te) and the third precursor (Sb) is 0.5 s, and the supply time of the first precursor (Ge) and the second precursor (Te) is varied. As shown in FIG. 3, when the supply time of the first precursor and the second precursor is 0.9 s, a component ratio of GeSbTe of the phase change material thin film is Ge(14.2): Sb(29.8): Te(56.0).

FIG. 4 is a graph illustrating X-ray diffraction analysis of the crystal structure of the phase change material thin film, in which a component ratio of GeSbTe is Ge(14.2): Sb(29.8): Te(56.0), according to an example embodiment. Along with an X-ray diffraction peak of a TiN substrate, FIG. 4 illustrates an X-ray diffraction peak of the crystal structure of GeSb₂Te₄, in which a composition ratio is 1:2:4.

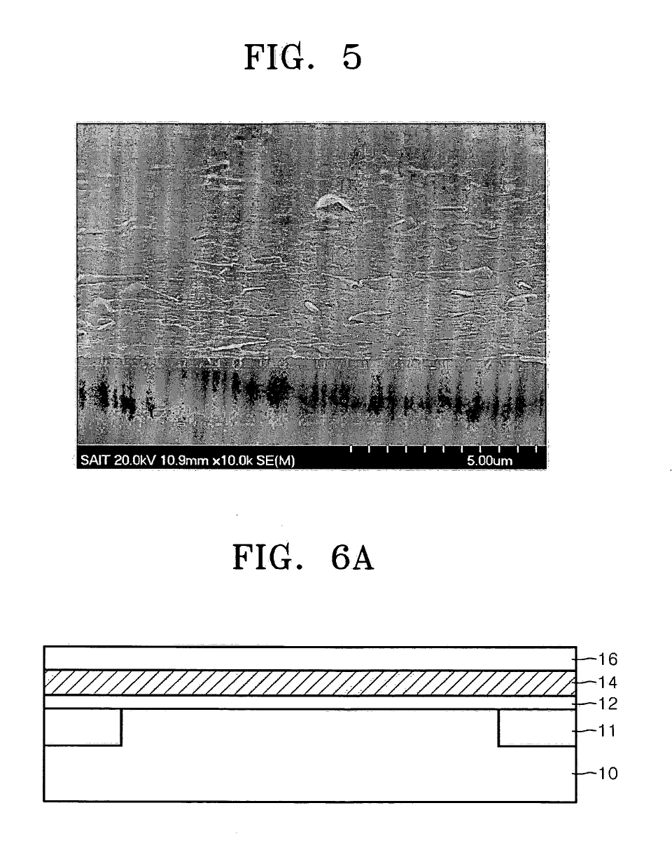

FIG. 5 is an electron microscope photograph illustrating the surface of the phase change material thin film of FIG. 4. As illustrated in FIG. 5, the surface of the phase change material thin film formed by a method, according to at least one example embodiment, has a more even and dense fine structure.

In a method of forming a GeSbTe thin film, according to at least one example embodiment, component ratios of the elements may be controlled more easily, a deposition speed of the thin film may be increased without using a plasma process, formation methods may be performed more easily and/or more simply.

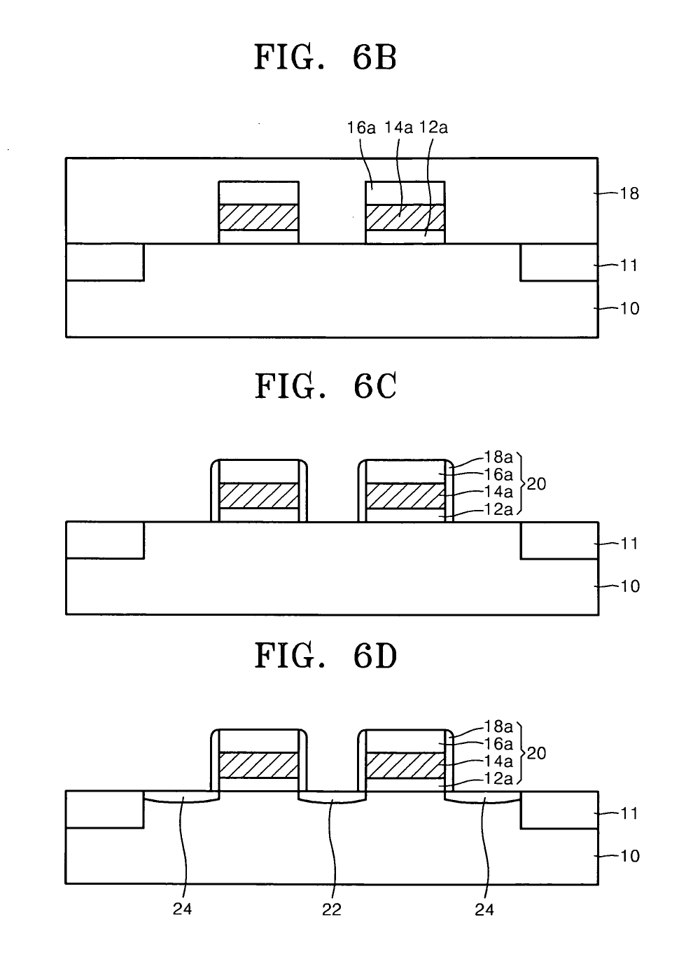

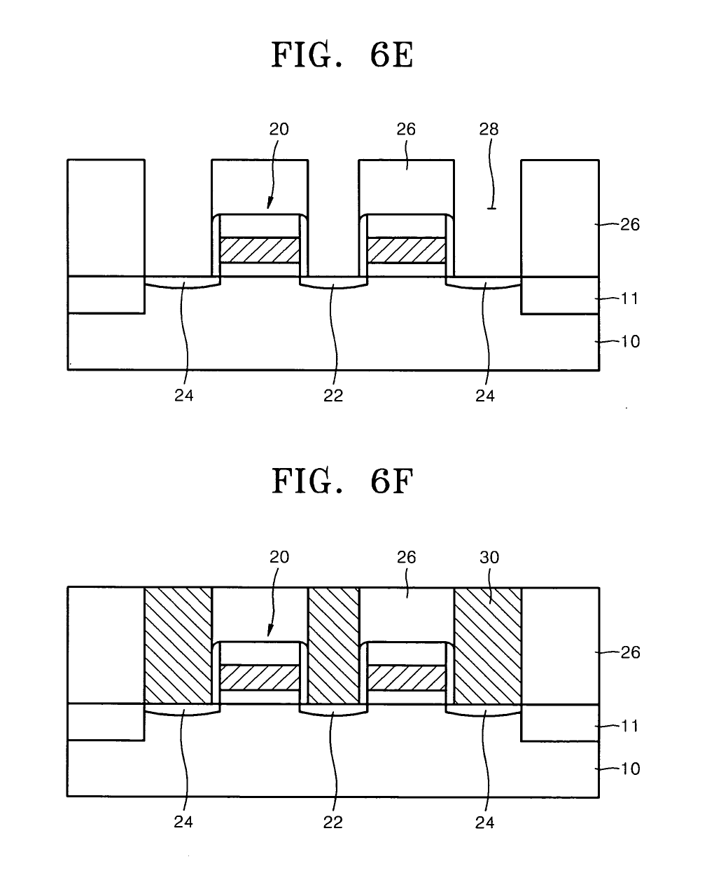

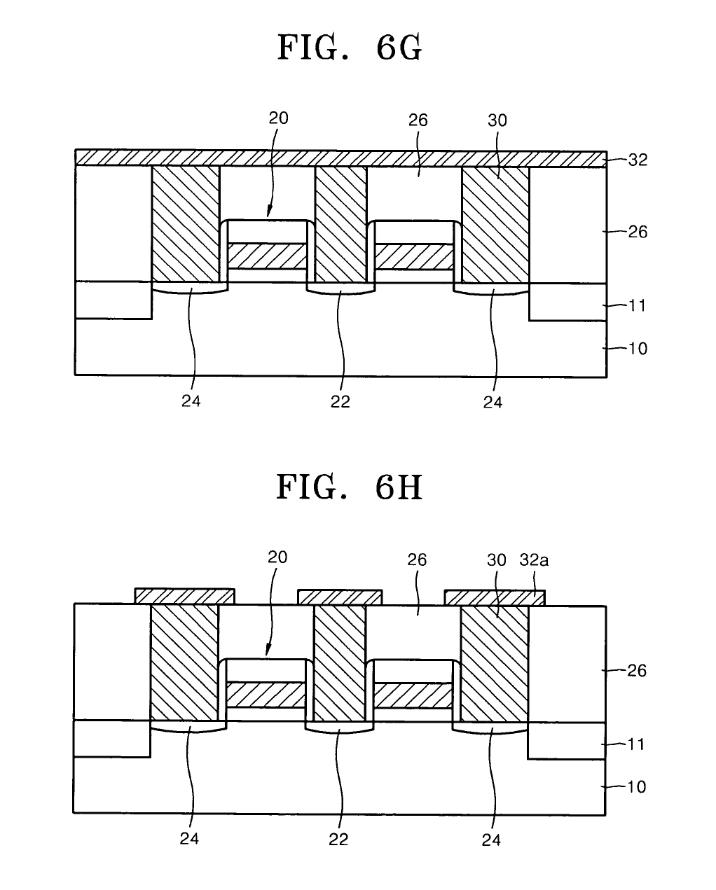

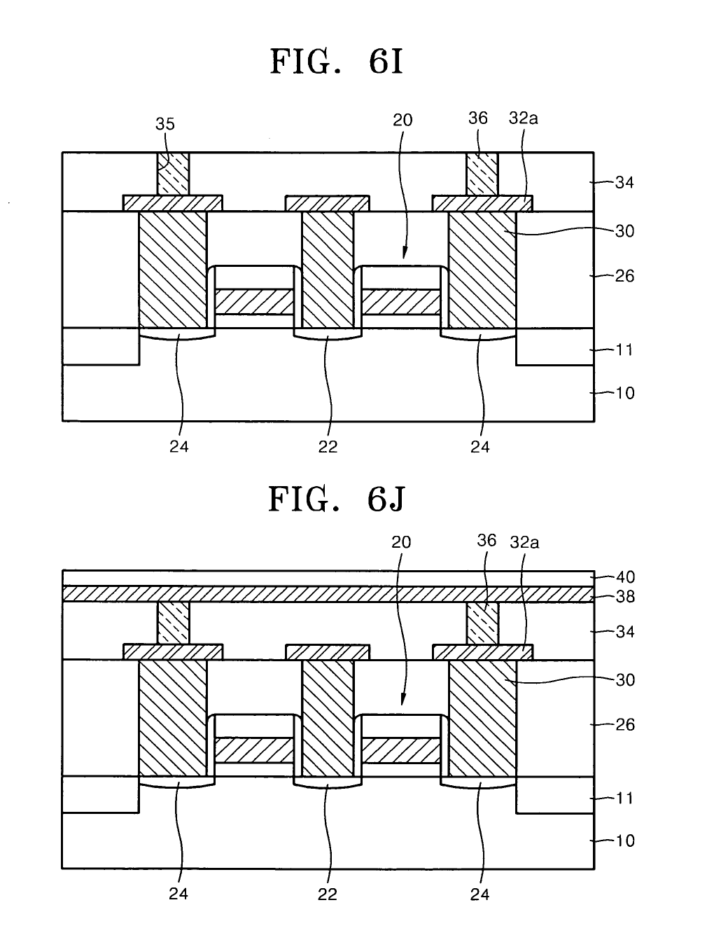

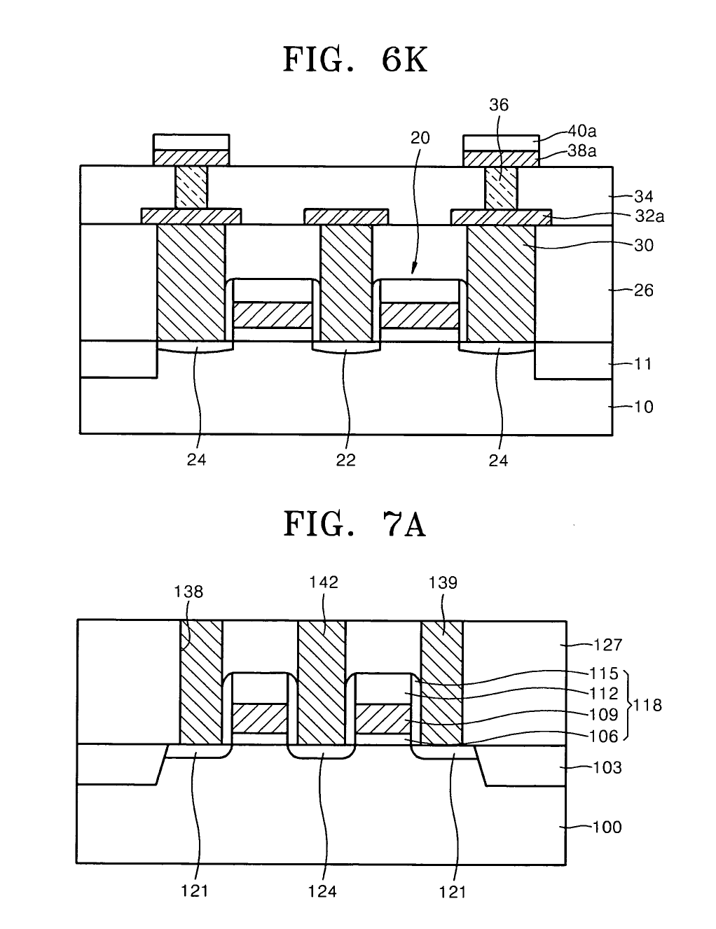

FIGS. 6A through 6H are sectional views of processing illustrating a method of manufacturing a phase change semiconductor memory device, according to an example embodiment.

Referring to FIG. 6A, a gate insulating layer 12, a gate conductive layer 14 and a gate mask layer 16 may be formed (e.g., sequentially) on an active region of a semiconductor substrate 10. The active region may be isolated by at least one isolation layer 11.

The gate insulating layer 12 may be formed using an oxide or metal oxide having a relatively high dielectric constant (e.g., a high-k dielectric). For example, the gate insulating layer 12 may be formed using silicon oxide, hafnium oxide, zirconium oxide, titanium oxide, tantalum oxide, aluminum oxide, or the like. The gate insulating layer 12 may be formed using a thermal oxidation process, a chemical vapor deposition process, a sputtering process, a plasma-enhanced chemical vapor deposition process, an atomic layer deposition process a high density plasma chemical vapor deposition process or any other suitable deposition process.

The gate conductive layer 14 may be formed using doped polysilicon, metal, metal silicide, or the like. For example, the gate conductive layer 14 may be formed using tungsten, aluminum, titanium, tantalum, tungsten silicide, titanium silicide, cobalt silicide, a metal silicide including a combination of these metallic elements or the like. The gate conductive layer 14 may be formed using a chemical vapor deposition process, a sputtering process, a plasma-enhanced chemical vapor deposition process, an atomic layer deposition process or any other suitable deposition process.

The gate mask layer 16 may be formed using a material having an etch selectivity with respect to the gate conductive layer 14 and/or the gate insulating layer 12. For example, the gate mask layer 16 may be formed using silicon nitride, silicon oxynitride, titanium oxynitride, or the like. The gate mask layer 16 may be formed using a chemical vapor deposition process, a plasma-enhanced chemical vapor deposition process, a sputtering process, an atomic layer deposition process or any other suitable deposition process.

Referring to FIG. 6B, the gate mask layer 16, the gate conductive layer 14 and the gate insulating layer 12 may be patterned to form a gate insulating layer pattern 12a, a gate electrode 14a, and a gate mask 16a. The gate insulating layer pattern 12a, a gate electrode 14a, and a gate mask 16a may be stacked (e.g., sequentially) on the semiconductor substrate 10. A first insulating layer 18 may be formed on the semiconductor substrate 10 to cover the gate mask 16a.

Referring to FIG. 6C, the first insulating layer 18 may be patterned (e.g., etched or anisotropically etched) to form a gate spacer 18a on each side wall of the gate insulating layer pattern 12a, the gate electrode 14a and the gate mask 16a. As a result, a gate structure 20 including the gate insulating layer pattern 12a, the gate electrode 14a, the gate mask 16a and the gate spacer 18a may be formed on the active region of the semiconductor substrate 10. The first insulating layer 18 may be formed using a nitride such as silicon nitride or the like.

Referring to FIG. 6D, first and second contact regions 22 and 24 may be formed in an exposed portion of the semiconductor substrate 10 using an ion implantation process to form a transistor including the gate structure 20 and the first and second contact regions 22 and 24. The gate structure 20 may be used as an ion implantation mask when forming the first and second contact regions 22 and 24. The first and second contact regions 22 and 24 may be source and drain regions of the transistor, respectively. In an alternative example embodiment, the transistor may be replaced with a PN junction diode.

Referring to FIG. 6E, a first interlayer insulating layer 26 may be formed on the substrate 10 to cover the transistor 20. A contact hole 28 may be formed in the first interlayer insulating layer 26 to expose the first and second contact regions 22 and 24. The first interlayer insulating layer 26 may be formed of, for example, an oxide such as BPSG, PSG, TEOS, PE-TEOS, USG, FOX, SOG, HDP-CVD oxide or the like. The first interlayer insulating layer 26 may be formed using a chemical vapor deposition process, a plasma-enhanced chemical vapor deposition process, an atomic layer deposition process, a high-density plasma chemical vapor deposition process or any other suitable deposition process. The contact hole 28 may be formed using a patterning patterning process, such as, etching or an anisotropic etching process.

Referring to FIG. 6F, the contact hole 28 may be filled with a conductor 30. The conductor 30 may be formed of impurity-doped polysilicon, metal, conductive metal nitride, or the like. For example, the conductor 30 may be formed using tungsten (W), titanium (Ti), tantalum (Ta), aluminum (Al), copper (Cu), tungsten nitride (WN), titanium nitride (TiN), tantalum nitride (TaN), aluminum nitride (AlN), titanium aluminum nitride (TiAlN), or the like. The conductor 30 may be formed using a sputtering process, a chemical vapor deposition process, an atomic layer deposition process, an electronic beam deposition process, a pulse laser deposition (PLD) process or any other suitable deposition process. One of a chemical mechanical polishing (CMP) process, an etch-back process or a combination process including the CMP process and the etch-back process may be performed to remove the conductor 30 to expose the first interlayer insulating layer 26.

Referring to FIG. 6G, a pad conductive layer 32 may be formed on the upper surface of the first interlayer insulating layer 26 and the conductor 30. The pad conductive layer 32 may be formed of impurity-doped polysilicon, metal, conductive metal nitride or the like. For example, the pad conductive layer may be formed using titanium aluminum nitride, tungsten nitride, titanium nitride, tantalum nitride, aluminum nitride, tungsten, titanium, tantalum, aluminum, copper or the like. The pad conductive layer 32 may be formed using a sputtering process, a chemical vapor deposition process, an atomic layer deposition process, an electronic beam deposition process, a pulse laser deposition process or any other suitable deposition process. The conductor 30 and the pad conductive layer 32, according to at least this example embodiment, may be formed of the same or substantially same material from among doped polysilicon, metal, conductive metal nitride or the like as described above.

Referring to FIG. 6H, a pad pattern 32a may be formed by performing a photolithography process and a patterning (e.g., an etch) process on the pad conductive layer 32.

Referring to FIG. 61, a second interlayer insulating layer 34 may be formed on the first interlayer insulating layer 26 and the pad pattern 32a. A contact hole 35 may be formed on the second interlayer insulating layer 34 to expose the pad pattern 32a. The contact hole 35 may be filled with conductor to form a lower electrode 36.

The second interlayer insulating layer 34 may include at least one oxide layer and/or nitride layer. For example, the oxide layer may be formed using PSG, BPSG, USG, SOG, TEOS, PE-TEOS, FOX, HDP-CVD oxide or the like, and the nitride layer may be formed using, for example, silicon nitride or the like. The second interlayer insulating layer 34 may be formed using a chemical vapor deposition process, a plasma-enhanced chemical vapor deposition process, an atomic layer deposition process, a high density plasma chemical vapor deposition process or any other suitable deposition process. According to at least one example embodiment, the first interlayer insulating layer 26 and the second interlayer insulating layer 34 may be formed of the same or substantially the same material from among the oxide and/or nitride as described above. Alternatively, the first and second interlayer insulating layers 26 and 34 may be formed of different materials from among the oxide and/or nitride.

The lower electrode 36 may be formed of impurity-doped polysilicon, metal conductive metal nitride or the like. For example, the lower electrode 36 may be formed using tungsten, titanium, titanium nitride, tantalum, tantalum nitride, molybdenum nitride (MoN), niobium nitride (NbN), titanium silicon nitride (TiSiN), aluminum, titanium aluminum nitride, titanium boron nitride (TiBN), zirconium silicon nitride (ZiSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN) or the like. These materials may be used singly, or two or more may be used in combination. Further, the lower electrode 36 may be formed using a sputtering process, a chemical vapor deposition process, an electronic beam deposition process, an atomic layer deposition process, a pulse laser deposition process or any suitable deposition process.

A patterning (e.g., an etch-back) process, a chemical mechanical polishing (CMP) process or the like may be used to at least partially remove the conductor for the lower electrode 36 until the second interlayer insulating layer 34 is exposed. The lower electrode 36 and the pad pattern 32a may be connected to each other inside the second interlayer insulating layer 34.

Referring to FIG. 6J, a phase change material thin film 38 and a conductor layer 40 may be formed (e.g., sequentially) on the second interlayer insulating layer 34 and the lower electrode 36.

The phase change material thin film 38 may include, for example, germanium-antimony-tellurium (GST). The phase change material film 38 may be formed using the method as described above with regard to FIGS. 1 and 2. Because formation processes of the phase change material thin film 38 may be the same or substantially the same as the processes described in reference to FIGS. 1 and 2, a detailed explanation thereof will be omitted for the sake of brevity.

The conductor layer 40 may be formed of impurity-doped polysilicon, metal, conductive metal nitride or the like. For example, the conductor layer 40 may be formed of tungsten, titanium, titanium nitride, tantalum, tantalum nitride, molybdenum nitride (MoN), niobium nitride (NbN), titanium silicon nitride (TiSiN), aluminum, titanium aluminum nitride, titanium boron nitride (TiBN), zirconium silicon nitride (ZiSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN) or the like. These materials may be used singly, or two or more may be used in combination. The conductor layer 40 may be formed using a sputtering process, a chemical vapor deposition process, an electronic beam deposition process, an atomic layer deposition process, a pulse laser deposition process or any suitable deposition process.

Referring to FIG. 6K, the conductor layer 40 and the phase change material thin film 38 may be patterned (e.g., etched) using, for example, a photolithography process to form a phase change material thin film pattern 38a and an upper electrode 40a. The phase change material thin film pattern 38a and the upper electrode 40a may be stacked (e.g., sequentially) on the lower electrode 36 and the second interlayer insulating layer 34. For example, the phase change material thin film pattern 38a may be disposed on the lower electrode 36 and the second interlayer insulating layer 34, and the upper electrode 40a may be disposed on the phase change material thin film pattern 38a. Each of the phase change material thin film pattern 38a and the upper electrode 40a may have an area a greater or substantially greater than that of the lower electrode 36. Additional processes may be performed to complete the fabrication of a memory device. The explanation of subsequent processes is well-known in the art, and therefore, has been omitted for the sake of brevity.

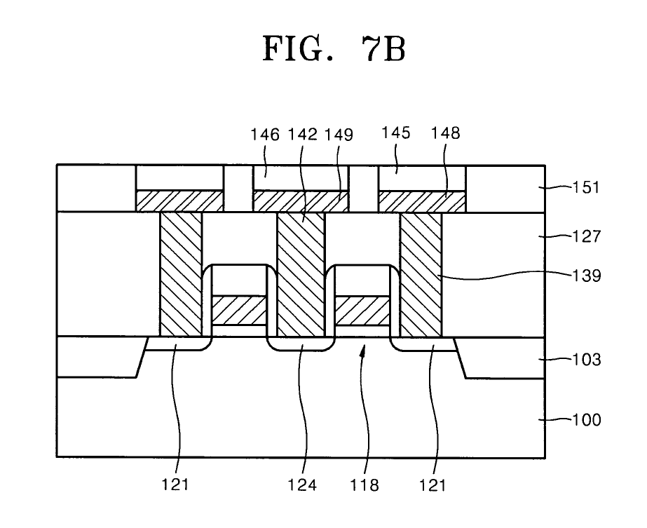

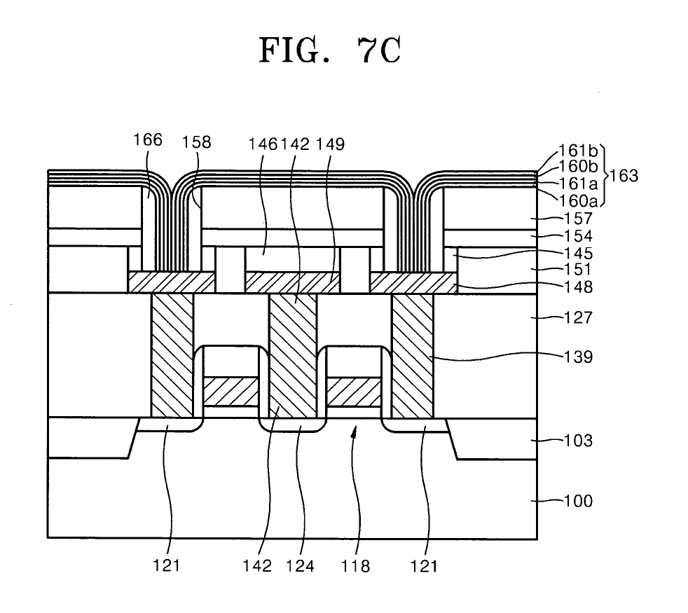

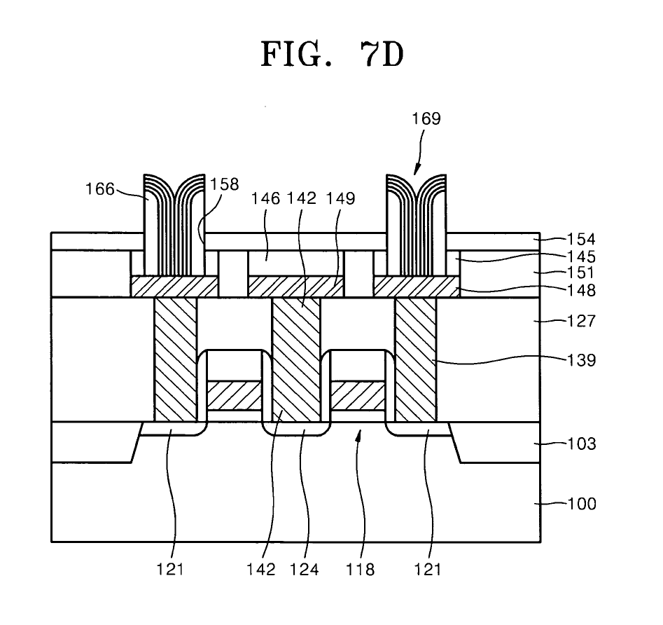

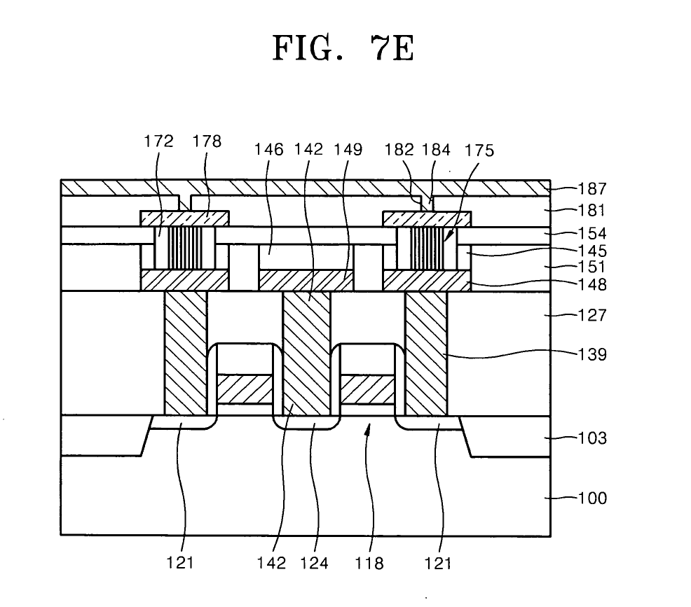

FIGS. 7A through 7E are sectional views of processing illustrating a method of manufacturing a phase change semiconductor memory device, according to another example embodiment.

Referring to FIG. 7A, an isolation layer 103 may be formed in a semiconductor substrate 100 defining an active region in the semiconductor substrate 100. A gate insulating layer, a gate conductive layer and a gate mask layer may be formed (e.g., sequentially) on the semiconductor substrate 100, and the gate mask layer, the gate conductive layer and the gate insulating layer may be patterned, to form a gate insulating layer pattern 106, a gate electrode 109 and a gate mask 112. According to at least this example embodiment, the gate electrode 109 may have a single layer structure such as a doped polysilicon layer, a metal layer, a conductive metal nitride layer or the like. In at least one other example embodiment, the gate electrode 109 may have a double-layered structure including a doped polysilicon layer, a metal layer, a conductive metal nitride layer or the like. The gate mask 112 may be formed using a material having an etch selectivity with respect to the gate electrode 109 and/or the gate insulating layer pattern 106.

After a first insulating layer is formed on the semiconductor substrate 100 to cover the gate mask 112, the first insulating layer may be patterned (e.g., etched or anisotropically etched) to form a gate spacer 118 on each side wall of the gate insulating layer pattern 106, the gate electrode 109 and the gate mask 112. A gate structure 118 including the gate insulating layer pattern 106, the gate electrode 109, the gate mask 112 and the gate spacer 115 may be formed on the semiconductor substrate 100.

An ion implantation process may be performed using the gate structures 118 as ion implantation masks to form first and second contact regions 121 and 124 in an exposed portion of the semiconductor substrate 100. The first and second contact regions 121 and 124 may be formed between the gate structures 118. As a result, transistors including gate structures 118 and the first and second contact regions 121 and 124, respectively, may be formed on the semiconductor substrate 100.

A first interlayer insulating layer 127 may be formed on the semiconductor substrate 100 to cover the gate structures 118. The first interlayer insulating layer 127 may be formed by depositing oxide using a chemical vapor deposition process, a plasma-enhanced chemical vapor deposition process, an atomic layer deposition process, a high density plasma chemical vapor deposition process or any suitable deposition process.

The first interlayer insulating layer 127 may be at least partially patterned (e.g., etched) using a photolithography process to form contact holes 138 exposing the first and second contact regions 121 and 124 in the first interlayer insulating layer 127.

A first conductive layer (not shown) may be formed on the first interlayer insulating layer 127 to at least partially (or completely) fill the contact holes 138. The first conductive layer may be formed by depositing doped polysilicon, metal, conductive metal nitride or the like, using a sputtering process, a chemical vapor deposition process, a plasma-enhanced chemical vapor deposition process, an atomic layer deposition process, an electronic beam deposition process, a pulse laser deposition process or any suitable deposition process.

The first conductive layer may be at least partially removed using a chemical mechanical polishing process, an etch-back process or the like to form first and second lower contacts 139 and 142 inside the contact holes 138. The first lower contact 139 may be formed on the first contact region 121 and the second lower contact 142 may be formed on the second contact region 124.

Referring to FIG. 7B, a second conductive layer (not shown) and a second insulating layer (not shown) may be formed (e.g., sequentially) on the first and second lower contacts 139 and 142 and the first interlayer insulating layer 127. The second insulating layer may be formed by depositing nitride or oxynitride using a chemical vapor deposition process, a plasma-enhanced chemical vapor deposition process, an atomic layer deposition process, a high density plasma chemical vapor deposition process or any suitable deposition process. The second conductive layer may be formed by depositing doped polysilicon, metal, conductive metal nitride or the like using a sputtering process, a chemical vapor deposition process, an atomic layer deposition process, an electronic beam deposition process, a pulse laser deposition process or any suitable deposition process.

The second insulating layer may be etched using a photolithography process to form a first insulating layer pattern 145 and a second insulating layer pattern 146 concurrently on the second conductive layer. The first insulating layer pattern 145 may be formed over the first lower contact 139 and the second insulating layer pattern 146 may be formed over the second lower contact 142.

The second conductive layer may be at least partially etched, using the first and second insulating layer patterns 145 and 146 as etch masks, to form a lower electrode 148 and a lower interconnection 149. The lower electrode 148 may be formed or disposed on the first lower contact 139, and electrically connected to the first contact region 121 through the first lower contact 139. The lower interconnection 149 may be disposed on the second lower contact 142, and may be electrically connected to the second contact region 124 through the second lower contact 142.

A second interlayer insulating layer 151 may be formed to cover the first and second insulating layer patterns 145 and 146 on the first interlayer insulating layer 127. The second interlayer insulating layer 151 may be formed by depositing oxide using a chemical vapor deposition process, a plasma-enhanced chemical vapor deposition process, an atomic layer deposition process, a high density plasma chemical vapor deposition process or any suitable deposition process.

The second interlayer insulating layer 151 may be at least partially removed using an etch-back process, a CMP process or the like until the first and second insulating layer patterns 145 and 146 are exposed. For example, the second interlayer insulating layer 151 may be polished using slurry including abrasives containing ceria having a higher etch selectivity between oxide and nitride, and the first and second insulating layer patterns 145 and 146 function as polishing stop layers, respectively.

Referring to FIG. 7C, a third insulating layer 154 may be formed on the second interlayer insulating layer 151, the first insulating layer pattern 145, and the second insulating layer pattern 146. The third insulating layer 154 may be formed by depositing nitride or oxynitride using a chemical vapor deposition process, a plasma-enhanced chemical vapor deposition process, an atomic layer deposition process, a high density plasma chemical vapor deposition process or any suitable deposition process.

A sacrificial layer 157 may be formed on the third insulating layer 154. The sacrificial layer 157 may be formed by depositing oxide using a chemical vapor deposition process, a plasma-enhanced chemical vapor deposition process, an atomic layer deposition process, a high density plasma chemical vapor deposition process or any suitable deposition process.

The sacrificial layer 157, the third insulating layer 154 and the first insulating layer pattern 145 may be at least partially patterned or etched using a photolithography process to form an opening 158 exposing the lower electrode 148.

A fourth insulating layer may be formed to at least partially (or completely) fill the opening 158 on the lower electrode 148 and the sacrificial layer 157, and the fourth insulating layer may be patterned (e.g., etched or anisotropically etched) to form a preliminary spacer 166 on side walls of the opening 158.

A phase change material thin film 163 may be formed to fill and/or bury the opening 158 on the lower electrode 148 and the sacrificial layer 157. The phase change material structure 163 may have a multi-layer structure. For example, the phase change material thin film 163 may include a plurality of first composite material layers 160a and 160b and a plurality of second composite material layers 161a and 161b. The first composite material layers 160a and 160b may include germanium and tellurium and the second composite material layers 161a and 161b may include antimony and tellurium. The phase change material thin film 163 may be formed using the same or substantially the same processes as described with regard to FIGS. 1 and 2.

Referring to FIG. 7D, the phase change material thin film 163 may be at least partially removed using a CMP process until the sacrificial layer 157 is exposed to form a preliminary phase change material thin film pattern 169 enclosed and/or buried in the opening 158. In this example, a preliminary spacer 166 may be disposed between the side wall of the preliminary phase change material thin film pattern 169 and the side wall of the opening 158.

The sacrificial layer 157 may be removed by etching to expose the third insulating layer 154. When the sacrificial layer 157 is removed, the preliminary phase change material thin film pattern 169 and the preliminary spacer 166 may upwardly protrude or extend from the third insulating layer 154.

Referring to FIG. 7E, the protruding upper portions of the preliminary phase change material thin film pattern 169 and the preliminary spacer 166 may be removed using a CMP process and/or an etch-back process to form a phase change material thin film pattern 175 and a spacer 172 concurrently on the lower electrode 148. For example, the phase change material thin film pattern 175 and the spacer 172 may be formed using slurry including abrasives containing ceria or the like. The third insulating layer 154 may function as a polishing stop layer. According to at least one example embodiment, by performing the polishing process (e.g., CMP process) sufficiently, the third insulating layer 154 may be removed during the formation of the phase change material thin film pattern 175 and the spacer 172.

An upper electrode 178 may be formed on the third insulating layer 154, the spacer 172 and the phase change material thin film pattern 175. The upper electrode 178 may be formed by depositing doped polysilicon, metal, conductive metal nitride or the like using a sputtering process, an atomic layer deposition process, an electronic beam deposition process, a chemical vapor deposition process, a pulse laser deposition process or any suitable deposition process.

A third interlayer insulating layer 181 may be formed to cover the upper electrode 178 on the third insulating layer 154. The third interlayer insulating layer 181 may be formed by depositing an oxide using a chemical vapor deposition process, a plasma-enhanced chemical vapor deposition process, an atomic layer deposition process, a high density plasma chemical vapor deposition process or any suitable deposition process.

After an upper contact hole 182 exposing the upper electrode 178 may be formed in the third interlayer insulating layer 181 using, for example, a photolithography process, an upper contact 184 at least partially filling the upper contact hole 182 may be formed on the upper electrode 178, and concurrently, an upper interconnection 187 may be formed on the upper contact 184 and the third interlayer insulating layer 181. The upper contact 184 and the upper interconnection 187 may be formed integrally using metal, conductive metal nitride or the like.

Subsequent processes may be performed (e.g., continuously) to complete the fabrication of a memory device. Because these subsequent processes are well-known in the art, a detailed discussion thereof has been omitted for the sake of brevity.

The phase change material thin film formed, according to at least some example embodiments, may be used as a recording layer of a phase change memory device. Because the phase change material thin film has a reduced reset current, the memory device having the phase change material thin film may be more highly integrated, and/or operate with a higher capacity and/or speed.

Using methods of forming a phase change material thin film, according to at least some example embodiments, the thin film may have a desired composition and/or a higher quality of the phase change material thin films may be formed as compared to the related art because the supply of precursors (e.g., Ge and Te precursors and/or Te and Sb precursors) may be performed independently and/or sequentially to form a GeSbTe thin film.

Using methods of forming a phase change material thin film, according to at least some example embodiments, a deposition speed of the thin film may increase and/or the formation method of the thin film may be more simple and/or easier. Additionally, formation methods, according to at least some example embodiments, may provide improved step coverage characteristics for realizing fabrication of a 3D structure of a more highly-integrated device.

As the phase change material thin film having improved phase change characteristics and/or improved electrical characteristics formed, according to at least some example embodiments, is used as a recording layer of a phase change memory device, the memory device may have higher integration of the device, higher capacity and/or increased speed.

As the phase change material thin film may be formed through more simplified processes, time and/or cost required to fabricate phase change semiconductor memory devices having phase change material thin films may be reduced (e.g., substantially or dramatically reduced).

Example embodiments have been described with regard to a phase change material thin film including germanium-antimony-tellurium (Ge—Sb—Te). However, in example embodiments, the phase change material thin film may include chalcogenide alloys such as arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the phase change material thin film may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the phase change material thin film may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the phase change material thin film is described above as being formed primarily of ternary phase-change chalcogenide alloys, the chalcogenide alloy of the phase change thin material could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂—S₂ alloy, for example.

In an example embodiment, the phase change material thin film may be made of a transition metal oxide having multiple resistance states, as described above. For example, the phase change material may be made of at least one material selected from the group consisting of NiO, TiO₂, HfO, Nb₂O₅, ZnO, WO₃, and CoO or GST (Ge₂Sb₂Te₅) or PCMO(PrₓCa₁₋ₓMnO₃). The phase change material thin film may be a chemical compound including one or more elements selected from the group consisting of S, Se, Te, As, Sb, Ge, Sn, In and Ag.

While example embodiments have been particularly shown and described with reference to the drawings, it will be understood by those of ordinary skill in the art that various changes in form and details may be made therein without departing from the spirit and scope of the present invention as defined by the following claims, and the present invention is not limited to the example structures and arrays illustrated herein.

What is claimed is:

1. A method of forming a phase change material thin film comprising:
forming a first thin film on a substrate by concurrently supplying a first precursor including Ge and a second precursor including Te into a reaction chamber; and
forming a second thin film on the first thin film by concurrently supplying the second precursor including Te and a third precursor including Sb into the reaction chamber.

2. The method of claim 1, wherein an inert gas and a reaction gas are supplied into the reaction chamber concurrently with the supplying of the first and second precursors, and the supplying of the second and third precursors.

3. The method of claim 1, wherein each of the first, second and third precursors are supplied along with a carrier gas including argon (Ar).

4. The method of claim 3, wherein a flow rate of the carrier gas of each precursor supplied during the forming of the first thin film is about 10 to about 400 sccm, inclusive.

5. The method of claim 3, wherein a component ratio of the first and second precursors supplied during the forming of the first thin film is about 1:1, and a total flow rate of the supplied carrier gases is about 200 sccm.

6. The method of claim 3, wherein during the forming of the first thin film the first and second precursors are supplied at a temperature of about 300 to about 500° C., inclusive, for about 0.1 to about 3.0 seconds, inclusive, under a pressure of about 0.5 to about 10 Torr, inclusive.

7. The method of claim 3, wherein a flow rate of the carrier gas of each precursor is about 10 to about 400 sccm, inclusive.

8. The method of claim 7, wherein a component ratio of the second and third precursor supplied when forming the second thin film is about 3:2, and a total flow rate of the supplied carrier gases is about 200 sccm.

9. The method of claim 7, wherein during the forming of the second thin film the second precursor and the third precursor are supplied at a temperature of about 300 to about 500° C., inclusive, for about 0.1 to about 3.0 seconds, inclusive, under a pressure of about 0.5 to about 10 Torr, inclusive.

10. The method of claim 1, further including,
purging non-reacted portions of the first and second precursors from the reaction chamber after forming the first thin film.

11. The method of claim 10, wherein the purging of the non-reacted portions of the first and second precursors includes,
stopping the supply of the first and second precursors to the reaction chamber, and
supplying an inert gas and a reaction gas to remove the non-reacted portions of the first and second precursors.

12. The method of claim 10, wherein the purging is performed using an inert gas and a reaction gas, the inert gas being argon (Ar) or nitrogen (N₂) gas, and the reaction gas being hydrogen (H₂) or ammonia (NH₃) gas.

13. The method of claim 12, wherein a flow rate of a mixture gas including argon (Ar) and hydrogen (H₂) as the inert gas and the reaction gas is about 10 to about 1000 sccm, inclusive.

14. The method of claim 12, wherein the flow rate of a mixture gas including argon (Ar) and hydrogen (H₂) is about 400 sccm.

15. The method of claim 1, further including,
purging non-reacted portions of the second and third precursors from the reaction chamber after forming the second thin film.

16. The method of claim 15, wherein the purging of the non-reacted portions of the second and third precursors includes,
stopping the supply of the second and third precursors to the reaction chamber, and
supplying an inert gas and a reaction gas to remove the non-reacted portions of the second and third precursors.

17. The method of claim 1, wherein the first precursor comprises at least one selected from the group consisting of (CH₃)₄Ge, (C₂H₅)₄Ge, (n-C₄H₉)₄Ge, (i-C₄H₉)₄Ge, (C₆H₅)₄Ge, (CH₂═CH)₄Ge, (CH₂CH═CH₂)₄Ge, (CF₂═CF)₄Ge, (C₆H₅CH₂CH₂CH₂)₄Ge, (CH₃)₃(C₆H₅)Ge, (CH₃)₃(C₆H₅CH₂)Ge, (CH₃)₂(C₂H₅)₂Ge, (CH₃)₂(C₆H₅)₂Ge, CH₃(C₂H₅)₃Ge, (CH₃)₃(CH═CH₂)Ge, (CH₃)₃(CH₂CH═CH₂)Ge, (C₂H₅)₃(CH₂CH═CH₂)Ge, (C₂H₅)₃(C₅H₅)Ge, (CH₃)₃GeH, (C₂H₅)₃GeH, (C₃H₇)₃GeH, Ge(N(CH₃)₂)₄, Ge(N(CH₃)(C₂H₅))₄, Ge(N(C₂H₅)₂)₄, Ge(N(i-C₃H₇)₂)₄ and Ge[N(Si(CH₃)₃)₂]₄.

18. The method of claim 1, wherein the second precursor comprises at least one selected from the group consisting of Te(CH₃)₂, Te(C₂H₅)₂, Te(n-C₃H₇)₂, Te(i-C₃H₇)₂, Te(t-C₄H₉)₂, Te(i-C₄H₉)₂, Te(Ch₂=CH)₂, Te(CH₂CH═CH₂)₂ and Te[N(Si(CH₃)₃)₂]₂.

19. The method of claim 1, wherein the third precursor comprises at least one selected from the group consisting of Sb(CH₃)₃, Sb(C₂H₅)₃, Sb(i-C₃H₇)₃, Sb(n-C₃H₇)₃, Sb(i-C₄H₉)₃, Sb(t-C₄H₉)₃, Sb(N(CH₃)₂)₃, Sb(N(CH₃)(C₂H₅))₃, Sb(N(C₂H₅)₂)₃, Sb(N(i-C₃H₇)₂)₃ and Sb[N(Si(CH₃)₃)₂]₃.

20. The method of claim 1, wherein the forming of the first thin film and the second thin film are repeatedly performed to form the phase change material thin film.

21. The method of claim 1, wherein the first thin film is a GeTe thin film and the second thin film is a SbTe thin film.

22. A method of manufacturing a phase change memory device comprising:
forming a lower electrode on a substrate;
forming a phase change material thin film on the lower electrode using the method of claim 1; and
forming an upper electrode on the phase change material thin film.

23. The method of claim 22, wherein an inert gas and a reaction gas are supplied into the reaction chamber concurrently with the supplying of the first and second precursors, and the supplying of the second and third precursors.

24. The method of claim 23, wherein the inert gas is argon (Ar) or nitrogen (N₂), and the reaction gas is hydrogen (H₂) or ammonia (NH₃).

25. The method of claim 22, further including,
purging non-reacted portions of the first and second precursors from the reaction chamber after forming the first thin film, and
purging non-reacted portions of the second and third precursors after forming the second thin film.

26. The method of claim 25, wherein the purging non-reacted portions of the first and second precursors includes,
stopping the supply of the first and second precursors into the reaction chamber, and
supplying an inert gas and a reaction gas to remove the non-reacted portions of the first and second precursors.

27. The method of claim 25, wherein the purging non-reacted portions of the second and third precursors includes,
stopping the supply of the second and third precursors into the reaction chamber, and
supplying an inert gas and a reaction gas to remove the non-reacted portions of the second and third precursors.

28. The method of claim 22, wherein the forming of the first thin film and the second thin film are repeatedly performed to form the phase change material thin film.

29. The method of claim 22, wherein each of the first, second and third precursors is supplied along with a carrier gas including argon (Ar) at a flow rate of about 10 to about 400 sccm, inclusive.

30. The method of claim 22, wherein a component ratio of the first and second precursors supplied during the forming of the first thin film is about 1:1, and a total flow rate of the supplied carrier gases is about 200 sccm.

31. The method of claim 22, wherein during the forming of the first thin film, the first and second precursor are supplied at a temperature of about 300 to about 500° C., inclusive, for about 0.1 to about 3.0 seconds, inclusive, under a pressure of about 0.5 to about 10 Torr, inclusive.

32. The method of claim 22, wherein during the forming of the second thin film, a component ratio of the supplied second and third precursors is about 3:2, and a total flow rate of the supplied carrier gases is about 200 sccm.

33. The method of claim 22, wherein during the forming of the second thin film, the second and third precursors are supplied at a temperature of about 300 to about 500° C., inclusive, for about 0.1 to about 3.0 seconds, inclusive, under a pressure of about 0.5 to about 10 Torr, inclusive.
